(19) United States
(12) Patent Application Publication
(10) Pub. No.: US 2026/0173785 A1
(43) Pub. Date: Jun. 18, 2026

(54) SEMICONDUCTOR MANUFACTURING EQPUIPMENT AND SUBSTRATE PROCESSING METHOD USING SAME

(71) Applicant: SEMES CO., LTD., Cheonan-si (KR)

(72) Inventors: Seung Jun OH, Cheonan-si (KR); Ahn Na SEO, Cheonan-si (KR); Jung Yoon CHOE, Cheonan-si (KR)

(73) Assignee: SEMES CO., LTD., Cheonan-si (KR)

(21) Appl. No.: 19/414,677

(22) Filed: Dec. 10, 2025

(30) Foreign Application Priority Data
Dec. 18, 2024 (KR) 10-2024-0189931

(51) Int. Cl. H10P 34/42; H01J 37/32; H10P 72/00; H10P 95/90

(52) U.S. Cl. CPC H10P 34/42; H01J 37/32724; H01J 37/32733; H10P 72/0436; H10P 95/90; H01J 37/32192; H01J 2237/336

(57) ABSTRACT

Semiconductor manufacturing equipment and a substrate processing method and the same are disclosed, the substrate processing method includes annealing a silicon substrate including an insulating film by supplying hydrogen gas to the silicon substrate; and supplying a laser beam to reduce an interface trap density between the insulating film and the silicon substrate.

### CROSS REFERENCE TO RELATED APPLICATION

The present application claims priority to Korean Patent Application No. 10-2024-0189931, filed Dec. 18, 2024, the entire contents of which is incorporated herein for all purposes by this reference.

### BACKGROUND OF THE INVENTION

### Field of the Invention

The present invention relates to semiconductor manufacturing equipment and a substrate processing method using the same. More specifically, the present invention relates to a substrate processing method for resolving process temperature constraints in a three-dimensional semiconductor manufacturing process.

### Description of the Related Art

The semiconductor manufacturing industry is continually striving to improve the processing power and power consumption of integrated circuits (ICs). Traditionally, this has been achieved by shrinking the minimum feature size. However, recent process limitations have made it difficult to continue reducing the minimum feature size. Consequently, stacking multiple device layers into three-dimensional (3D) ICs is attracting attention as an approach to improving processing power and power consumption in the ICs.

3D IC technologies include multilithic technology that integrates each of the stack targets after independently completing the front-end-of-line (FEOL) process (or front-end process) and electrically interconnects them through through-silicon vias (TSVs), and monolithic technology that sequentially forms multiple stack targets directly on a single semiconductor substrate (e.g., a wafer).

Although multilithic technology has an advantage of no process restrictions because the semiconductor process of each layer is carried out independently, it has disadvantages such as low vertical wiring density and limitations in thinning due to wafer bonding. Consequently, active research and investment are being focused on monolithic technology, which may achieve ideal vertical wiring density, reduce wiring length, and achieve thinner structures using thin interlayer dielectric (ILD).

In contrast, monolithic technology has limitations due to high-temperature processing conditions required to form devices and wiring structures on a single wafer and then stack and form other devices on top of them. For example, there are limitations with the deterioration of the characteristics and reliability of lower-layer devices, such as high-performance Si CMOS as upper devices are formed under high-temperature processing conditions. Furthermore, there are limitations on the materials available for interconnect metal wiring and associated performance degradation.

### SUMMARY OF THE INVENTION

Accordingly, the present invention has been made keeping in mind the above problems occurring in the prior art, and an objective of the present invention is to provide a substrate processing method for improving device characteristics while addressing limitations on process temperature.

The challenges addressed by the present invention are not limited to those mentioned above, and other challenges not mentioned will be readily apparent to those skilled in the art from the description below.

According to an embodiment of the present invention, a substrate processing method may include a hydrogen annealing step of annealing a silicon substrate including an insulating film by supplying hydrogen gas to the silicon substrate; and a laser beam supply step of supplying a laser beam to reduce an interface trap density between the insulating film and the silicon substrate.

According to an embodiment of the present invention, a semiconductor manufacturing equipment may include an index block including a carrier in which a substrate is stored; a processing block including a plasma device and a laser beam irradiation device for performing a processing procedure on the substrate; a substrate transfer block including a substrate transfer robot for loading or unloading the substrate; and a control device, in which the plasma device may anneal the silicon substrate including an insulating film; and the laser beam irradiation device may supply a laser beam to the silicon substrate including the insulating film to reduce an interface trap density between the insulating film and the substrate.

According to an embodiment of the present invention, a semiconductor manufacturing equipment may include an index block having a substrate stored therein; a processing block including a plasma device and a laser beam irradiation device for performing a processing procedure on a silicon substrate including an insulating film; a substrate transfer block including a substrate transfer robot for loading or unloading the substrate; and a control device, in which the plasma device may perform a hydrogen annealing step to convert hydrogen gas into plasma to allow hydrogen ions and hydrogen radicals to be penetrated into the insulating film, and the laser beam irradiation device may perform a laser beam supply step of suppling the laser beam to the substrate to allow the hydrogen ions and hydrogen radicals penetrated into the insulating film to move to an interface between the insulating film and the substrate, to reduce a trap density at the interface.

According to the present invention, a hydrogen annealing step is performed at a temperature of 450° C. or lower to allow hydrogen ions and hydrogen radicals to be penetrated into an insulating film formed on a silicon substrate.

By supplying a laser beam to the silicon substrate including the insulating film into which hydrogen ions and hydrogen radicals are penetrated, the hydrogen ions and hydrogen radicals move to an interface between the insulating film and the substrate, thereby reducing the interface trap density between the silicon substrate and the insulating film.

This overcomes the limitations on the hydrogen annealing process temperature and improves the switching performance of semiconductor devices.

However, the effects of the present invention are not limited to those described above, and other unmentioned effects will be clearly understood by those skilled in the art from the drawings below.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a schematic diagram illustrating a monolithic integrated circuit according to an embodiment of the present invention;

FIG. 2 is a diagram illustrating a semiconductor manufacturing facility according to an embodiment of the present invention;

FIG. 3a is a diagram illustrating a plasma device according to an embodiment of the present invention;

FIG. 3b is a diagram illustrating a plasma device according to another embodiment of the present invention;

FIG. 4 is a diagram illustrating a laser beam irradiation device according to an embodiment of the present invention;

FIG. 5 is a flowchart illustrating a substrate processing method according to an embodiment of the present invention;

FIG. 6 is a diagram illustrating changes in a cross-sectional shape of a substrate depending on a substrate processing method, according to an embodiment of the present invention; and

FIG. 7 shows data measuring an interface trap density between a substrate and an insulating film, according to an embodiment of the present invention.

### DETAILED DESCRIPTION OF THE INVENTION

Hereinafter, with reference to the attached drawings, embodiments of the present invention will be described in detail so that those skilled in the art may easily implement the invention. However, the present invention may be implemented in various different forms and is not limited to the embodiments described herein.

In describing embodiments of the present invention, if a detailed description of a related, well-known function or configuration is deemed to unnecessarily obscure the gist of the present invention, such detailed description will be omitted, and parts with similar functions and operations will be designated by the same reference numerals throughout the drawings.

At least some of the terms used in this specification are defined in consideration of their functions in the present invention and may vary depending on the user, operator, intent, custom, etc. Therefore, such terms should be interpreted based on the contents of the entire specification.

Furthermore, in this specification, the singular form also includes the plural form unless specifically stated otherwise. In the specification, when it is said that a component is included, unless otherwise specifically stated, this does not mean that other components are excluded, but rather that other components may be included.

Meanwhile, the sizes, shapes, and line thicknesses of components in the drawings may be somewhat exaggerated for ease of understanding.

Hereinafter, embodiments of the present invention will be described in detail with reference to the attached drawings. In describing with reference to the attached drawings, identical or corresponding components are given the same reference numerals regardless of the drawing numbers, and redundant descriptions thereof will be omitted.

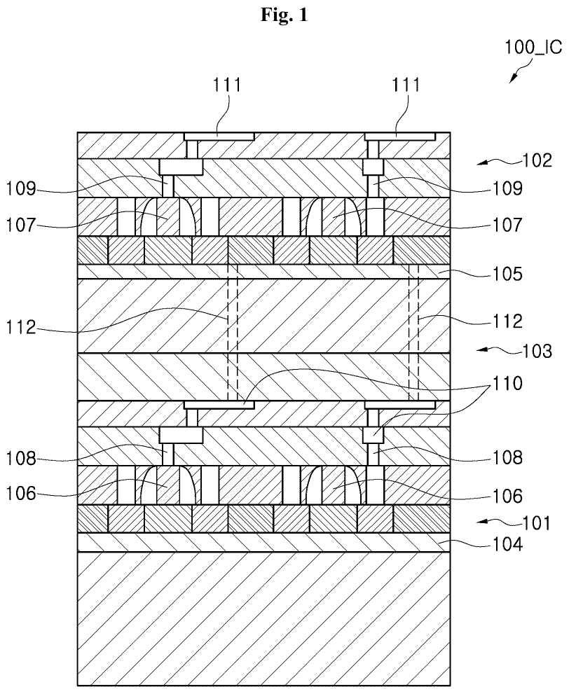

FIG. 1 is a schematic diagram of a monolithic integrated circuit according to an embodiment of the present invention.

Referring to FIG. 1, a monolithic integrated circuit 100_IC may include a first integrated circuit 101, a second integrated circuit 102, and a thermal shielding layer 103. The second integrated circuit 102 may be positioned on the upper portion of the first integrated circuit 101, and the thermal shielding layer 103 may be positioned between the first integrated circuit 101 and the second integrated circuit 102. The monolithic integrated circuit 100_IC may be formed in the following order: the first integrated circuit 101, the thermal shielding layer 103, and the second integrated circuit 102. The first integrated circuit 101 and the second integrated circuit 102 may include substrates 104 and 105, a series of semiconductor devices 106 and 107 (e.g., p-type field effect transistors, n-type field effect transistors, NAND gates, NOR gates, flip-flops, or other logic circuits) disposed on each of the substrates 104 and 105, a series of vias 108 and 109, and wirings 110 and 111 individually disposed on the individual semiconductor devices 106 and 107, respectively. Additionally, the monolithic integrated circuit 100_IC may include a series of vias 112 disposed within the thermal shielding layer 103 to connect the semiconductor devices 106 in the first integrated circuit 101 to the semiconductor devices 107 in the second integrated circuit 102.

The present invention relates to a method for forming the semiconductor devices 107 on the substrate 105 of the second integrated circuit 102.

According to an embodiment of the present invention, a substrate W may be a substrate in which an insulating film is formed on a silicon substrate. The insulating film may be a silicon oxide film, and a metal oxide film may be further formed on the silicon oxide film. Herein, the metal oxide film may be a high-k material such as hafnium oxide (HfO2), but is not limited thereto. In the present disclosure, the silicon substrate may be interchangeably used with a substrate.

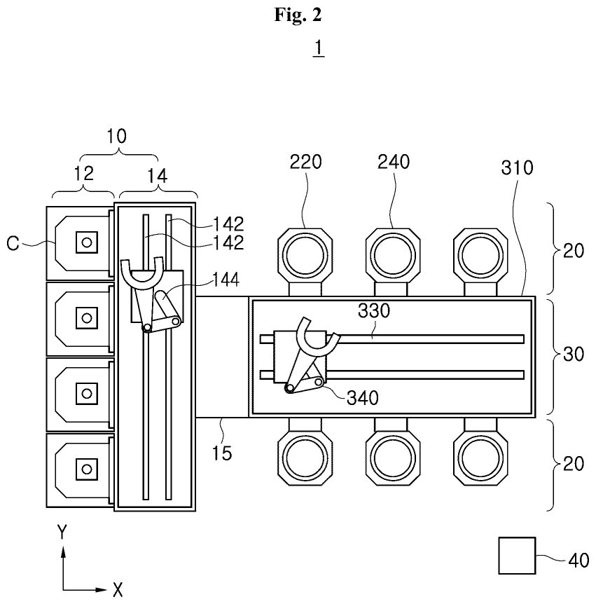

FIG. 2 is a drawing illustrating semiconductor manufacturing equipment according to an embodiment of the present invention.

Referring to FIG. 2, the semiconductor manufacturing equipment 1 may include an index block 10, a processing block 20, a substrate transfer block 30 for transferring substrates between the index block 10 and the processing block 20, and a control device 40. According to an embodiment of the present invention, the index block 10 and the processing block 20 may be sequentially arranged in a single row.

The index block 10 includes a load port 12 on which a carrier C having a substrate stored therein is mounted, and an index frame 14 for removing the substrate from the carrier C mounted on the load port 12 or loading the substrate that has completed a processing from the carrier C. The load port 12 is located on the opposite side of the processing block 20 relative to the index frame 14. A plurality of carriers C containing substrates are placed on the load port 12.

An index robot 144 may be provided within the index frame 14. The index robot 144 may be configured to be moved along a rail 142. The index robot 144 may be configured to receive substrates from the carrier C and transfer them to the load lock chamber 15 where the substrates are temporarily stored, or receive substrates temporarily stored in the load lock chamber 15 and transfer them into the carrier C.

The processing block 20 is a device for performing a processing step on a substrate, and may include one or more plasma devices 220 and laser beam irradiation devices 240. According to an embodiment of the present invention, the plasma device 220 may anneal the substrate by converting hydrogen gas into plasma and supplying it to the substrate; and the laser beam irradiation device 240 may supply a laser beam to the substrate to reduce the trap density at the interface between the substrate and the insulating film.

The substrate transfer block 30 is arranged adjacent to the processing block 20 and configured to receive substrates from the load lock chamber 15 and transfer them to the processing block 20, or transfer substrates that have completed a processing step in the processing block 20 to the load lock chamber 15. The substrate transfer block 30 may include a rail 330 arranged along the direction in which the processing device 200 is arranged, and a substrate transfer robot 340 that transfers the substrates while moving along the rail 330. The substrate transfer robot 340 may transfer the substrate while moving inside a return chamber 310.

The control device 40 may comprehensively control the operation of the semiconductor manufacturing equipment 1 configured as described above. The control device 40 may be, for example, a computer and may include a Central Processing Unit (CPU), a Random Access Memory (RAM), a Read Only Memory (ROM), auxiliary storage, etc. The CPU operates based on programs stored in the ROM or the auxiliary storage, or process conditions, to control the operation of the semiconductor manufacturing equipment 1. Furthermore, the computer-readable program required for control may be stored on a storage medium. Examples of such a storage medium include a flexible disk, a Compact Disc (CD), a CD-ROM, a hard disk, flash memory, or a DVD. The control device 40 may be installed either inside or outside the semiconductor manufacturing equipment 1. When the control device 40 is installed outside it, the control device 40 may control the equipment 1 via wired or wireless communication.

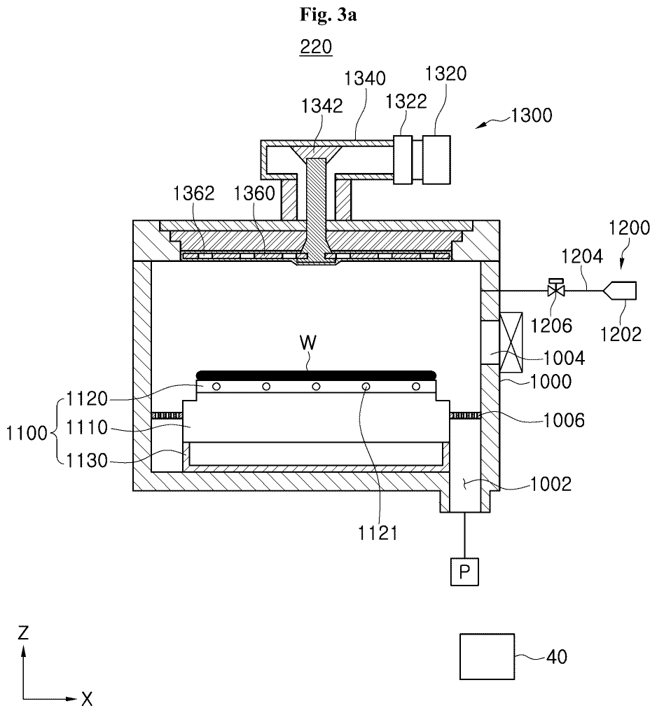

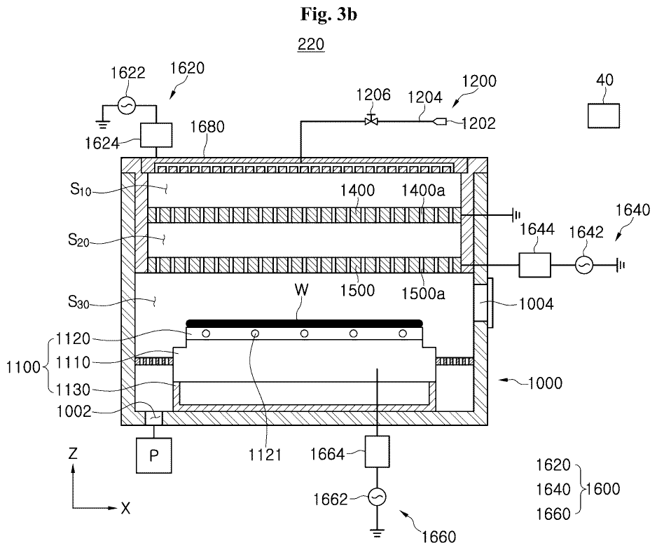

FIG. 3a is a diagram illustrating a plasma device according to an embodiment of the present invention.

Referring to FIG. 3a, the plasma device 220 may include a chamber 1000, a substrate support unit 1100, a gas supply unit 1200, and a microwave unit 1300.

The chamber 1000 has a processing space where a process is performed. The chamber 1000 may be provided with an exhaust port 1002 at its lower portion, and the exhaust port 1002 may be connected to an exhaust line, which is equipped with a pump P. The exhaust port 1002 may discharge reaction byproducts generated during the process and gases remaining within the chamber 1000 to the outside of the chamber 1000 through the exhaust line. Herein, the internal space of the chamber 1000 may be decompressed to a predetermined pressure.

The chamber 1000 may have an opening 1004 formed on its sidewall. The opening 1004 may react as a passage through which a substrate W enters and exits the chamber 1000. This opening 1004 may be configured to be opened and closed by a door assembly.

The baffle unit 1006 may serve to exhaust plasma process byproducts, unreacted gases, etc. The baffle unit 1006 may be installed between the inner wall of the chamber 1000 and the electrostatic chuck 1120 described below. The baffle unit 1006 may be provided in an annular ring shape and may have a plurality of through-holes extending vertically. The flow of process gas may be controlled depending on the number and shape of the through-holes in the baffle unit 1006.

The substrate support unit 1100 may be positioned in the lower region within the chamber 1000. The substrate support unit 1100 may support the substrate W using electrostatic force. However, the present embodiment is not limited thereto, and the substrate W may be supported in various ways, such as mechanical clamping or vacuum.

The substrate support unit 1100 may include a support 1110 and an electrostatic chuck 1120 disposed on the upper surface of the support 1110. The electrostatic chuck 1120 may be configured to electrostatically attract the substrate W and may include a ceramic layer having electrodes interposed therebetween.

A heating member 1121 may be provided within the substrate support unit 1100 to maintain the substrate W at a process temperature. The heating member 1121 may be a heating coil to heat the substrate W. According to an embodiment of the present invention, the substrate W may be heated to a temperature of 450° C. or lower using the heating member 1121.

A support member 1130 may be provided below the support 1110 and may support the substrate support unit 1100 and the electrostatic chuck 1120. The support member 1130 has a cylindrical shape with a predetermined height and may have a space therein.

The gas supply unit 1200 may supply gas required for the process into the chamber 1000. The gas supply unit 1200 may include a gas supply source 1202, a gas supply line 1204, and a gas injection nozzle. The gas supply line 1204 may connect the gas supply source 1202 to the gas injection nozzle. The gas supply line 1204 may supply gas stored in the gas supply source 1202 to the gas injection nozzle. The gas supply line 1204 may be equipped with a gas supply valve 1206 for opening and closing the passage or controlling the flow rate of the fluid flowing through the passage. The gas supplied from the gas supply unit 1200 according to an embodiment of the present invention may be hydrogen gas, such as H2.

Although FIG. 3a only illustrates one gas supply source 1202 and one gas supply valve 1206, the present invention may include multiple gas supply sources capable of supplying multiple gases to the chamber 1000 and multiple gas supply valves capable of independently controlling the supply of each gas.

The microwave unit. 1300 may apply microwaves to the processing space of the chamber 1000 to change the supplied gas into plasma. It may include a microwave generator 1320, a waveguide 1340, and an antenna 1360.

The microwave generator 1320 generates microwaves, and the generated microwaves may have a frequency of approximately 2.3 GHZ to 2.5 GHz. The microwave generator 1320 may be connected to the waveguide 1340, and a matching network 1322 may be provided between the microwave generator 1320 and the waveguide 1340. The matching network 1322 may match microwaves supplied through the microwave generator 1320 to a predetermined frequency.

The waveguide 1340 may be provided in a tubular shape with a polygonal or circular cross-section. The inner surface of the waveguide 1340 may be provided as a conductor. For example, the inner surface of the waveguide 1340 may be provided as a metal or silver. The waveguide 1340 may provide a path through which microwaves generated by the microwave generator 1320 are transmitted and may be connected to then antenna 1360.

A coaxial converter 1342 is located within the waveguide 1340. One end of the coaxial converter 1342 is fixed to the inner surface of the waveguide 1340. The coaxial converter 1342 may be provided in a cone shape with one end having a smaller cross-sectional area than the other end in the side of the microwave generator 1320. Microwaves transmitted through the inner space of the waveguide 1340 have their mode changed by the coaxial converter 1342, which then are propagated downward. For example, microwaves may be converted from a transverse electric mode (TE mode) into a transverse electromagnetic mode (TEM mode).

The antenna 1360 may be provided in a plate shape. For example, the antenna 1360 may be provided as a thin circular plate. A plurality of slot holes 1362 may be formed in the antenna 1360. The slot holes 1362 is not arranged in a limited manner, but may be arranged in a concentric, spiral, or radial shape, or may be uniformly distributed across the entire surface of the antenna 1360.

The control device 40 according to an embodiment of the present invention may supply gas to the processing space within the chamber 1000 to perform a hydrogen annealing step described below, and perform control so that the gas may be converted into plasma by the microwave unit 1300. Herein, the control device 40 may control the heating member 1121 of the substrate support unit 1100 to control the temperature of the substrate W to 450° C. or lower. In addition, the control device 40 may perform control so that the substrate W that has completed the hydrogen annealing step using the plasma device 220 moves to the laser beam irradiation device 240. Specifically, the substrate W may be a substrate in which hydrogen ions and hydrogen radicals are penetrated into the interior of the insulating film in the silicon substrate including the insulating film (i.e., the silicon substrate provided with the insulating film). In one embodiment, the laser may include a pulsed laser, and wavelengths ranging from infrared (IR) to ultraviolet (UV) may be employed. For example, a laser wavelength of 1000 nm or less may be used to control the temperature of the substrate, with shorter wavelengths being advantageous for energy transfer. The pulse width may be controlled on the nanosecond (ns) scale. The irradiation may be performed using a scanning method. The laser output may range from 10 mW to 3000 mW, and in one embodiment, the output is 300 mW or less with an irradiation time of 60 seconds. The hydrogen ions and hydrogen radicals, upon receiving the supplied energy, may migrate between the silicon and the insulating film when the substrate temperature is 450° C. or less.

FIG. 3b is a drawing illustrating a plasma device according to another embodiment of the present invention.

The plasma device of FIG. 3b may generate plasma within a chamber using a high-frequency power module, unlike the plasma device of FIG. 3a.

Referring to FIG. 3b, the plasma device 220 may include an ion blocker 1400, a shower head 1500, and a high-frequency power module 1600.

The ion blocker 1400 and the shower head 1500 may be positioned on the upper portion of the substrate support unit 1100. The ion blocker 1400 may be positioned on the upper portion of the shower head 1500 and may be installed to be faced to the bottom surface of the chamber 1000. The ion blocker 1400 may be made of silicon or may alternatively be made of metal. The ion blocker 1400 may be provided in a plate shape, such as a circular plate shape. A plurality of through holes 1400a may be formed in the ion blocker 1400.

The shower head 1500 is positioned on the lower portion of the ion blocker 1400 and may be installed to be faced to the substrate support unit 1100. The shower head 1500 may be manufactured using a metal material. The shower head 1500 may be provided in a plate shape, such as a circular plate shape. A plurality of gas injection holes 1500a may be formed in the shower head 1500 to supply gas.

According to an embodiment of the present invention, a space partitioned by the chamber 1000 and the ion blocker 1400 may be referred to as a first space S₁₀, and a space partitioned by the ion blocker 1400 and the shower head 1500 may be referred to as a second space S₂₀. In addition, an area where a substrate support unit 1100 is arranged under the shower head 1500 may be referred to as a substrate processing space S₃₀.

A high-frequency power module 1600 is connected to the chamber 1000 to generate plasma. According to an embodiment of the present invention, the high-frequency power module 1600 may include a first high-frequency power module 1610, a second high-frequency power module 1620, and a third high-frequency power module 1630. Furthermore, a capacitively coupled plasma (CCP) source may be used to generate plasma, but the present invention is not limited thereto. For example, an inductively coupled plasma (ICP) source may be used to generate plasma.

The first high-frequency power module 1620 may be provided at the upper portion of the chamber 1000. An upper electrode 1680 may be formed at the upper portion of the chamber 1000, and a first high-frequency power source 1622 and a first impedance matcher 1624 may be connected thereto. Additionally, the second high frequency power module 1640 may be provided to the shower head 1500. The second high frequency power source 1642 and the second impedance matcher 1644 may be connected to the shower head 1500. The ion blocker 1400 may be grounded. Additionally, the third high frequency power module 1660 may be provided to the support 1110. The third high frequency power source 1662 and the third impedance matcher 1664 may be connected to the support 1110. Unlike the illustration, only some of the first to third high frequency power modules 1620, 1640 and 1660 may be provided to the plasma device 220.

Hydrogen gas may be supplied from the gas supply unit 1200 into the interior of the chamber 1000, and the supplied hydrogen gas may be converted into plasma by the high-frequency power module 1600. As a result, a substrate including an insulating film may be annealed, and hydrogen ions and hydrogen radicals may be penetrated into the interior of the insulating film. In FIG. 3b, the gas supply unit 1200 is shown as being connected to the upper electrode 1680, but the present invention is not limited thereto. For example, the gas supply unit 1200 may be connected to the shower head 1500, so that the gas supplied from the gas supply unit 1200 may be directly supplied to the substrate processing space S₃₀.

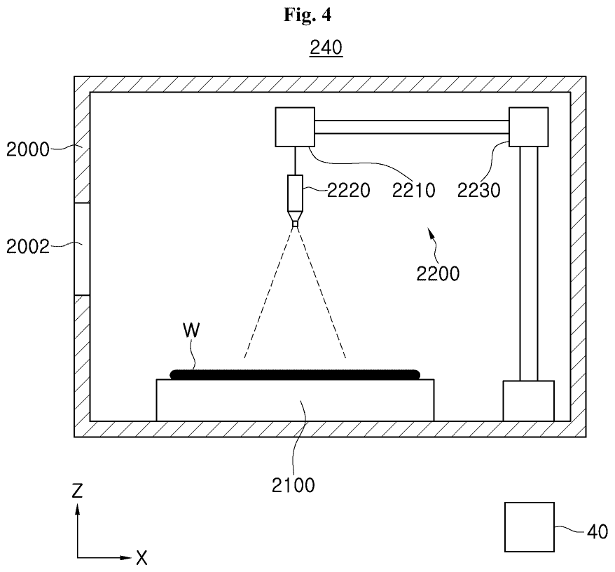

FIG. 4 is a drawing illustrating a laser beam irradiation device according to an embodiment of the present invention.

Referring to FIG. 4, the laser beam irradiation device 240 may include a housing 2000, a substrate support unit 2100, and a laser beam irradiation unit 2200.

The housing 2000 may be provided in a rectangular cylindrical shape that has a processing space inside. An opening 2002 may be formed in a sidewall of the housing 2000. The opening 2002 may function as a passage through which a substrate W enters and exits the housing 2000. According to an embodiment of the present invention, the substrate W may be a hydrogen-annealed substrate, in which hydrogen ions and hydrogen radicals are penetrated into the insulating film using the plasma device 220. A door may be installed in the opening 2002, and may be configured to open and close the opening 2002.

The substrate support unit 2100 may support the substrate W that has completed hydrogen annealing. The substrate support unit 2100 may be provided to have a diameter larger than that of the substrate W.

The laser beam irradiation unit 2200 may irradiate a laser beam to the substrate W that has completed the hydrogen annealing process. The laser beam irradiation unit 2200 may include a laser beam generation unit 2210, a laser beam irradiation unit 2220, and a laser beam driving unit 2230. The laser beam generation unit 2210 may generate a laser beam. The laser beam irradiation unit 2220 may convert the laser beam generated by the laser beam generation unit 2210 into an appropriate shape and size to irradiate the laser beam to the substrate W. Irradiating the hydrogen-annealed substrate with the laser beam using the laser beam irradiation unit 2200 may cause hydrogen ions and hydrogen radicals that have penetrated into the insulating film to move to the interface between the insulating film and the silicon substrate. Specifically, irradiating the substrate W with the laser beam may cause energy to be supplied to the hydrogen ions and hydrogen radicals that have penetrated into the insulating film. This allows hydrogen ions and hydrogen radicals to move to the interface between the insulating film and the silicon substrate. By filling the vacancies at the interface between the insulating film and the silicon substrate with hydrogen ions and hydrogen radicals, the interface trap density between the insulating film and the silicon substrate may be reduced. The wavelength of the laser beam supplied from the laser beam irradiation unit 2200 to the substrate W may be smaller than the band gap of the insulating film. According to the present invention, the substrate W may be heated by the supplied laser beam, in which the temperature of the substrate W may be 450° C. or lower.

According to an embodiment of the present invention, the control device 40 places the hydrogen-annealed substrate W inside the housing 2000 to perform the laser beam irradiation step described below, and supplies the laser beam to the substrate W using the laser beam irradiation unit 2200. Furthermore, the control device 40 may control the intensity and supply time of the laser beam according to process conditions.

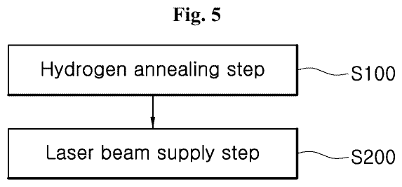

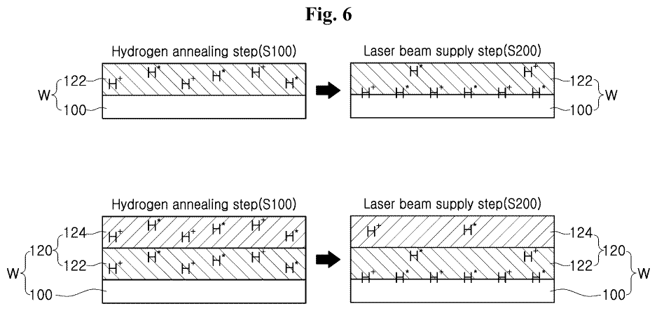

FIG. 5 is a flowchart illustrating a substrate processing method according to an embodiment of the present invention; and FIG. 6 is a diagram illustrating changes in a cross-sectional shape of a substrate depending on a substrate processing method, according to an embodiment of the present invention. Since the substrate processing method according to the present invention is performed using the semiconductor manufacturing equipment described in FIGS. 2 through 4, the substrate processing method will be described with reference to FIGS. 2 through 6.

Referring to FIGS. 2 through 6, the method may include a hydrogen annealing step S100 of annealing the substrate including an insulating film by supplying hydrogen gas to the silicon substrate; and a laser beam supply step S200 of supplying a laser beam to reduce trap density at the interface between the insulating film and the silicon substrate. The hydrogen annealing step and the laser beam supply step (S100 through S200) constitute one cycle and may be repeated at least once. In an embodiment, the hydrogen annealing step may be preceded with the laser beam supply stem in each cycle. The substrate processing method according to an embodiment of the present invention may be performed at a temperature of 450° C. or lower.

The hydrogen annealing step S100 is a step of supplying hydrogen gas to the silicon substrate 100 including the insulating film 120 to anneal the substrate W. The hydrogen gas may be supplied from the gas supply unit of the plasma device 220 into the chamber 1000 and then converted into plasma. The hydrogen gas converted into plasma may be decomposed into hydrogen ions and hydrogen radicals, and such hydrogen ions and hydrogen radicals may penetrate into the insulating film 120. Specifically, the hydrogen ions and hydrogen radicals may penetrate into defective portions within the silicon oxide film 122 and the metal oxide film 124, thereby reducing the fixed charge density (FCD) of the insulating film 120. In addition, some hydrogen radicals may be adsorbed on dangling bond portions of the surface of the silicon substrate 100. The substrate W that has completed the hydrogen annealing step S100 may be taken out from the plasma device 220.

The laser beam supply step S200 is a step of supplying a laser beam to the substrate W that has completed the hydrogen annealing step S100. The substrate W taken out from the plasma device 220 may be introduced into a laser beam irradiation device 240. By supplying a laser beam to the substrate W introduced into the laser beam irradiation device 240, the substrate W may be heated. The wavelength of the laser beam according to an embodiment of the present invention may be smaller than the band gap of the insulating film 120. The supplied laser beam may cause the hydrogen ions and hydrogen radicals that have penetrated into the insulating film 120 to move to the interface between the insulating film 120 and the silicon substrate 100. Specifically, irradiating the substrate W with a laser beam may cause energy to be supplied to the hydrogen ions and hydrogen radicals that have penetrated into the insulating film 120. As a result, the hydrogen ions and hydrogen radicals may move to the interface between the insulating film 120 and the silicon substrate 100. As the vacancies existing at the interface between the insulating film 120 and the silicon substrate 100 are filled with the hydrogen ions and hydrogen radicals, the interface trap density between the insulating film 120 and the silicon substrate 100 may be reduced. In addition, silicon atoms of the silicon substrate 100 may move so that the silicon atoms may have a more stable energy state by the hydrogen radicals and the laser beam. As the crystallinity of the silicon atoms is improved accordingly, stable bonding may be achieved, and thus the surface roughness of the substrate W may be improved. In addition, since the heat generated for a short time by the laser beam does not reach the silicon substrate 100 but only affects the insulating film 120, damage to the silicon substrate 100 due to heat may be prevented. The intensity and supply time of the laser beam may vary depending on the process conditions.

Table 1 and Table 2 below show data measuring the fixed defect concentration of insulating films in Examples and Comparative Examples of the present invention.

Table 1 shows data measuring the fixed defect concentration in a structure in which a silicon oxide film is formed on a silicon substrate. In Table 1, a Comparative Example shows data measuring the fixed defect concentration of a reference specimen that was not subjected to any processing, and Examples 1 and 2 show data measuring the fixed defect concentration after performing a hydrogen annealing step. The hydrogen annealing step in Example 2 was performed for a longer period of time than in Example 1.

TABLE 1
N_{f}(cm⁻²)

Number of times

| Specimen | 1 | 2 |
|---|---|---|
| Comparative Example | 4.73 × 10¹² | 4.30 × 10¹² |
| Example 1 | 2.42 × 10¹² | 2.52 × 10¹² |
| Example 2 | 3.93 × 10¹² | 3.88 × 10¹² |

As a result, the fixed defect concentrations of Examples 1 and 2 were reduced compared to those of the Comparative Example. In other words, it was confirmed that the fixed defect concentration was reduced by performing the hydrogen annealing step. Since increasing the time of the hydrogen annealing step did not necessarily decrease the fixed defect concentration when comparing Examples 1 and 2, it is desirable to perform the hydrogen annealing step at an optimal time to maximize the reduction in the fixed defect concentration.

Table 2 shows the results of measuring the fixed defect concentration in a structure in which a silicon oxide film and a metal oxide film (HfO2) were formed on a silicon substrate. In Table 2, a Comparative Example shows data measuring the fixed defect concentration of a reference specimen that had not completed any processing, while the Example shows data measuring the fixed defect concentration after performing the hydrogen annealing step.

TABLE 2
N_{f}(cm⁻²)

| | Number of times | | | |
|---|---|---|---|---|
| Specimen | 1 | 2 | 3 | 4 |
| Comparative | 5.90 × 10¹² | 5.81 × 10¹² | 5.17 × 10¹² | 5.14 × 10¹² |
| Example | | | | |
| Example | 3.76 × 10¹² | 4.20 × 10¹² | 3.02 × 10¹² | 3.12 × 10¹² |

As a result, it was confirmed that performing the hydrogen annealing step reduced the fixed defect concentration even when silicon oxide and metal oxide films were formed on a silicon substrate.

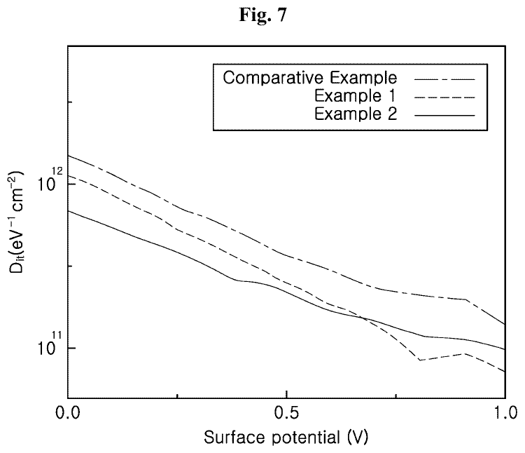

FIG. 7 shows data measuring the interface trap density according to the intensity of the laser beam according to an embodiment of the present invention.

The specimens in FIG. 7 have a structure in which a silicon oxide film and a metal oxide film (HfO2) are formed on a silicon substrate. The comparative example shows data measuring the interface trap density of a reference specimen that is not subjected to any processing; and Examples 1 and 2 show data measuring the interface trap density between the substrate and the insulating film after performing the hydrogen annealing step and the laser beam supply step. The laser beam power in Example 2 is stronger than that in Example 1.

Referring to FIG. 7, it may be seen that performing the laser beam supply step reduces the interface trap density between the silicon substrate and the insulating film. When comparing Example 1 and Example 2, it can be seen that the surface potential increases, the interface trap density does not decrease proportionally even when the power supplying the laser beam increases, and therefore it is desirable to perform the laser beam supply step with the optimal laser beam supply power to minimize the interface trap density.

As described above, the hydrogen annealing step and the laser beam irradiation step may allow for improving the interface properties between the silicon substrate and the insulating film. Specifically, the hydrogen annealing step allows hydrogen ions and hydrogen radicals to penetrate into defective portions within the silicon oxide and metal oxide films, thereby reducing the fixed charge density (FCD) of the insulating film. Furthermore, some hydrogen radicals may adsorb onto dangling bonds on the silicon substrate surface. Furthermore, the laser beam irradiation step allows the hydrogen ions and hydrogen radicals that are penetrated into the silicon oxide and metal oxide films to move to the interface between the insulating film and the silicon substrate, allowing them to fill the vacancies present at the interface. Consequently, the interface trap density between the insulating film and the silicon substrate may be reduced, which results in improving the switching performance of semiconductor devices.

The above description merely exemplifies the technical idea of the present invention, and those skilled in the art will appreciate that various modifications and variations may be made without departing from the essential characteristics of the present invention. Therefore, the embodiments described in the present invention are not intended to limit the technical idea of the present invention, but rather to illustrate it, and the technical idea of the present invention is not limited by these embodiments. The scope of protection of the present invention should be interpreted by the following claims, and all technical ideas within a scope equivalent thereto should be interpreted as being included in the scope of the rights of the present invention.

### DESCRIPTION OF REFERENCE NUMERALS

1: semiconductor manufacturing equipment
10: index block
20: processing block
30: substrate transfer block
40: control device
220: plasma device
240: laser beam irradiation device

1. A substrate processing method, comprising:
a hydrogen annealing step of annealing a silicon substrate provided with an insulating film by supplying hydrogen gas to the silicon substrate; and
a laser beam supply step of supplying a laser beam to reduce an interface trap density between the insulating film and the silicon substrate.

2. The substrate processing method of claim 1, wherein the hydrogen annealing step and the laser beam supply step are repeated at least once.

3. The substrate processing method of claim 1, wherein the hydrogen annealing step and the laser beam supply step are performed at a temperature of 450° C. or lower.

4. The substrate processing method of claim 1, wherein the hydrogen annealing step causes the hydrogen gas to be supplied by converting the hydrogen gas into plasma to cause hydrogen ions and hydrogen radicals to penetrate into the insulating film.

5. The substrate processing method of claim 4, wherein the laser beam supply step causes the hydrogen ions and the hydrogen radicals penetrated into the insulating film to move to an interface between the insulating film and the silicon substrate, to reduce the interface trap density.

6. The substrate processing method of claim 1, wherein the insulating film is a silicon oxide film.

7. The substrate processing method of claim 6, wherein the insulating film further comprises a metal oxide film.

8. The substrate processing method of claim 7, wherein the metal oxide film is HfO2.

9. A semiconductor manufacturing equipment, comprising:
an index block including a carrier in which a substrate provided with an insulating film is stored;
a processing block including a plasma device and a laser beam irradiation device for performing a processing procedure on the substrate;
a substrate transfer block including a substrate transfer robot for loading or unloading the substrate; and
a control device,
wherein the plasma device anneals the substrate provided with the insulating film; and
wherein the laser beam irradiation device supplies a laser beam to the substrate provided with the insulating film to reduce an interface trap density between the insulating film and the substrate.

10. The semiconductor manufacturing equipment of claim 9, wherein the plasma device comprises:
a chamber having a processing space inside;
a substrate support unit positioned within the processing space and configured to support the substrate provided with the insulating film;
a gas supply unit supplying hydrogen gas to the processing space; and
a microwave unit converting the hydrogen gas into plasma,
wherein the substrate is annealed by converting the hydrogen gas into the plasma to supply hydrogen ions and hydrogen radicals to the substrate provided with the insulating film.

11. The semiconductor manufacturing equipment of claim 10, wherein the hydrogen ions and the hydrogen radicals penetrate into the insulating film.

12. The semiconductor manufacturing equipment of claim 10, wherein the substrate support unit comprises a heating element for heating the substrate provided with the insulating film, and
the control device controls the heating element to maintain a temperature of the substrate at 450° C. or lower.

13. The semiconductor manufacturing equipment of claim 11, wherein the laser beam irradiation device comprises:
a housing having a processing space inside;
a substrate support unit positioned within the processing space and configured to support the annealed substrate; and
a laser beam irradiation unit supplying the laser beam to the substrate,
wherein the laser beam is supplied to the annealed substrate to allow the hydrogen ions and the hydrogen radicals penetrated into the insulating film to move to an interface between the insulating film and the substrate.

14. The semiconductor manufacturing equipment of claim 9, wherein the insulating film is a silicon oxide film.

15. The semiconductor manufacturing equipment of claim 14, wherein the insulating film further includes a metal oxide film, and the metal oxide film is HfO2.

16. A semiconductor manufacturing equipment, comprising:
an index block having a substrate stored therein;
a processing block including a plasma device and a laser beam irradiation device for performing a processing procedure on a silicon substrate provided with an insulating film;
a substrate transfer block including a substrate transfer robot for loading or unloading the substrate; and
a control device,
wherein the plasma device performs a hydrogen annealing step to convert a hydrogen gas into plasma to allow hydrogen ions and hydrogen radicals to be penetrated into the insulating film, and
wherein the laser beam irradiation device performs a laser beam supply step of suppling a laser beam to the silicon substrate to allow the hydrogen ions and the hydrogen radicals penetrated into the insulating film to move to an interface between the insulating film and the silicon substrate, to reduce an interface trap density.

17. The semiconductor manufacturing equipment of claim 16,
wherein the plasma device comprises:
a chamber having a processing space inside;
a substrate support unit positioned within the processing space and configured to support the silicon substrate including the insulating film;
a gas supply unit supplying hydrogen gas to the processing space; and
a microwave unit converting the hydrogen gas into plasma,
wherein the laser beam irradiation device comprises:
a housing having a processing space inside;
a substrate support unit positioned within the processing space and configured to support the hydrogen-annealed substrate; and
a laser beam irradiation unit supplying the laser beam to the silicon substrate.

18. The semiconductor manufacturing equipment of claim 16,
wherein the hydrogen annealing step and the laser beam supply step performed by the plasma device and the laser beam irradiation device are performed at a temperature of 450° C. or less.

19. The semiconductor manufacturing equipment of claim 16,
wherein the insulating film is a silicon oxide film or a laminated film of a silicon oxide film and a metal oxide film.

20. The semiconductor manufacturing equipment of claim 16,
wherein the laser beam irradiation device supplies a wavelength smaller than a band gap of the insulating film to the silicon substrate.
